(19) United States
(12) Patent Application Publication
(10) Pub. No.: US 2003/0131938 A1
(43) Pub. Date: Jul. 17, 2003

(54) Apparatus for preparing and supplying slurry for CMP apparatus

(75) Inventor: Shigeki Kobayashi, Tokyo (JP)

Correspondence Address: NIXON PEABODY, LLP, 8180 GREENSBORO DRIVE, SUITE 800, MCLEAN, VA, 22102, US

(73) Assignee: Tokyo Seimitsu Co., Ltd., Tokyo (JP)

(21) Appl. No.: 10/339,594

(22) Filed: Jan. 10, 2003

(30) Foreign Application Priority Data
Jan. 11, 2002 (JP) 2002-4418

(51) Int. Cl. H01L 21/302

(52) U.S. Cl. 156/345.12; 156/345.18

(57) ABSTRACT

The apparatus is provided for preparing and/or supplying a slurry for a CMP apparatus in which a device is adopted to avoid drying a slurry thereby eliminating coagulation and solidification of the slurry. A slurry preparation apparatus comprises a tank for preparing and/or supplying the slurry, a humidity sensor located inside the tank, a humidifying air supply device for supplying humidifying air into the tank. Humidity in the tank is measured by the humidity sensor, and the amount of humidifying air to be supplied from the humidifying air supply device is controlled according to the measurements, thereby conditioning inside the tank to a desired humidity.

### BACKGROUND OF THE INVENTION

1. Field of the Invention

The present invention relates to a method and apparatus for preparing and supplying a slurry for a Chemical Mechanical Polishing (CMP) apparatus.

2. Description of the Related Art

As semiconductor integrated circuit design rules shrink, CMP has gained popularity in processes for planarizing layers such as interlayer films. Most of slurries used for CMP comprise a solid-liquid dispersion system in which fine particles are dispersed in an aqueous solution with reagents such as a pH adjuster. Colloidal silica, fumed silica, cerium oxide and the like are typically used for these fine particles.

A common apparatus for preparing a slurry for a polishing apparatus is of a type shown in a cross-section in FIG. 2. The slurry preparation apparatus can also function as a slurry tank (slurry feeder) for supplying the slurry.

In FIG. 2, the slurry preparation apparatus 1 has pipes 2, 3 and 4 inserted into a bath through an upper lid. A pipe 5 is connected to the bottom of the bath. The pipe 2 is for supplying the stock slurry solution (as it is purchased from a manufacturer) and the pipe 3 for supplying an additive. The pipe 5 is for drawing and supplying the slurry to a slurry feeder, and the pipe 4 for returning the slurry back into the bath.

The pipes 4 and 5 are connected to a CMP apparatus, and used for supplying the slurry from the slurry preparation apparatus 1 to the CMP apparatus while circulating the slurry. A pipe 6 is connected between the pipes 4 and 5, and serves as a bypass between the pipes 4 and 5 that circulate the slurry between the slurry preparation apparatus 1 and the CMP apparatus. Additionally, a pump 7 and valves 8 and 9 are provided as auxiliary equipment.

The preparation of the slurry is accomplished by supplying the stock slurry solution and the additive through the pipes 2 and 3, respectively, and stirring them with a stirrer, not shown. Similarly; the stock slurry solution and the additive are supplied and stirred to prepare the slurry as it is lessened in the slurry preparation apparatus 1.

In some instances, a slurry is not initially prepared in the slurry preparation apparatus 1 as described above, and an externally and separately prepared slurry is supplied. In this case, the pipe 2 and/or the pipe 3 are used only to add the stock slurry solution and/or additive.

The above-described conventional slurry preparation apparatus 1 suffers from a problem that it does not avoid drying a slurry to coagulate and solidify. While the slurry is being supplied, a liquid surface level in the slurry preparation apparatus 1 falls as much as the slurry is used. At this time, the slurry is deposited on a wall surface in an area from a level before the slurry is used down to a level as much as the slurry is used.

The deposited slurry then dries to coagulate and solidify on the wall surface. The coagulated and solidified slurry clod may fall off from the wall surface and mix with the slurry liquid. The slurry clod with large size thus mixed with the slurry liquid after it coagulates and solidifies may cause damages (microscratches) on a wafer during CMP, resulting in a degraded wafer quality or reduced wafer yield.

Japanese Patent Application Publication No. 11-165259 discloses as a solution to such a phenomenon, an arrangement such that it avoids drying a slurry by applying water drops on the wall section of a mixing bath with, for example, a cooling section provided on the wall section of the mixing bath. This arrangement, however, can add complexity to the system, and is not easily maintained.

Another solution has been adopted such that without providing such a device, it uses a filter to filter off slurry clod with large size mixed with the slurry liquid after it coagulates and solidifies. However, the filter is easily clogged when complete filtering is intended, and a less-clogging filter makes filtering insufficient, unavoidably causing microscratches.

### SUMMARY OF THE INVENTION

The present invention has been made in view of these circumstances, and it is an object of the present invention to provide an apparatus for preparing and/or supplying a slurry for a CMP apparatus in which a device is adopted to avoid drying a slurry thereby eliminating coagulation and solidification of the slurry.

To attain the above-described object, the present invention is directed to an apparatus for preparing and/or supplying a slurry for a CMP apparatus, comprising: a tank for preparing and/or supplying the slurry; a humidity sensor located inside the tank; and a humidifying air supply device for supplying humidifying air into the tank, wherein humidity in the tank is measured by the humidity sensor, and an amount of the humidifying air to be supplied from the humidifying air supply device is controlled according to the measured humidity in the tank, thereby conditioning inside the tank to a desired humidity.

According to the present invention, humidity in a tank is measured by a sensor capable of measuring humidity in the tank for preparing a slurry and for other purposes, and the amount of humidifying air to be supplied is controlled according to the measurements. The present invention, therefore, provides for high accuracy for conditioning humidity, the humidity is automatically measured, and humidifying air is automatically supplied.

It is possible to maintain an inner wall of a tank in a wet condition with humidifying air supplied into the tank using a humidifying air supply device (for example, commercially available humidifier) without adopting an arrangement such as that according to the present invention. This may lead to an inconvenience that a slurry in the bath is diluted with condensed water if unlimitedly humidified. Additionally, temperature and humidity in a tank changing over time must flexibly be addressed.

The present invention thus has an unprecedented arrangement and effect.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1 shows a schematic view of the entire configuration of an apparatus for preparing and/or supplying a slurry according to the present invention; and

FIG. 2 shows a schematic sectional view of an example of a conventional apparatus for preparing a slurry.

### DETAILED DESCRIPTION OF THE PREFERRED EMBODIMENTS

A preferred embodiment of a method and apparatus for preparing and/or supplying a slurry for a CMP apparatus (hereinafter referred to as slurry preparation apparatus, etc.) according to the present invention will now be described with reference to the drawings.

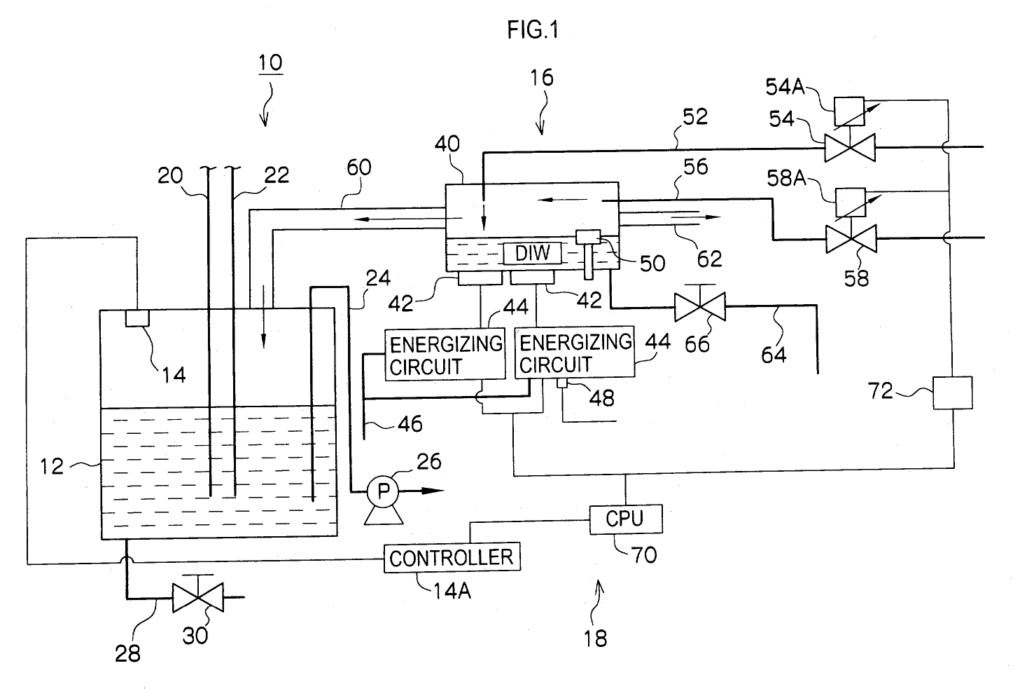

FIG. 1 shows a schematic view of the entire configuration of a slurry preparation apparatus 10 according to the present invention. The slurry preparation apparatus 10 comprises a tank 12 for preparing and/or supplying a slurry, a humidity sensor 14, a humidifying air supply device 16, and a control device 18 for controlling the system, etc.

The tank 12 for preparing a slurry and for other purposes is in a cylindrical shape. Materials for the tank 12 include, for example, polypropylene, a metal coated with polytetrafluoroethylene resin, and the like. Pipes 20 and 22 are in communication with inside of the tank 12 through an upper lid (not shown) thereof. The pipe 20 is for supplying the stock slurry solution (as it is purchased from a manufacturer) and the pipe 22 for supplying an additive. A pipe 24 is also provided through the upper lid. The pipe 24 is connected to a pump 26 and routed to a polishing apparatus for drawing and supplying the slurry to the CMP apparatus. A pipe 28 is connected to the bottom of the tank 12, and a valve 30 located on the end of the pipe 28 can be operated to drain the content of the tank 12.

A humidifying air pipe 60 is connected to the upper lid of the tank 12 in a manner that humidifying air can be supplied into the tank 12 from a humidifying chamber 40, as described below.

The tank 12 is provided with a stirrer (not shown) for stirring the slurry. Stirring with the stirrer is accomplished by rotating blades located on the end of a shaft that is driven by a motor.

The humidity sensor 14 may be any type of humidity sensor that can sense humidity in the tank 12 and extract it as an electrical signal. Such a humidity sensor that may be used includes, for example, the model TA205 from Toplas Engineering Co., Ltd. (the model REX-F400 from Rika-Kogyosha may be used as a controller 14A). The indication of the humidity sensor ranges from 0 to 100%, and 0 to 1 V can be obtained as an analog output.

The analog output from the controller (converter) 14A is sent to a computer 70. The analog output from the controller 14A is sent to and recorded on a data logger (not shown).

The humidifying air supply device 16 comprises the humidifying chamber 40 that is a closed bath, atomizing units 42 fixed on outside of the bottom of the humidifying chamber 40, energizing circuits 44 that drive the atomizing units 42, a power supply line 46 for the energizing circuits 44, a temperature sensor 48 fixed on the energizing circuit 44 and used by a protection circuit for the energizing circuit 44, a level sensor 50 located inside the humidifying chamber 40 to determine the level of pure water in the humidifying chamber 40, a pure water pipe 52 in communication with inside of the humidifying chamber 40 therethrough, a valve 54 that is connected to the pure water pipe 52 and turns on/off the supply of pure water from a pure water source (not shown), a solenoid 54A that causes the valve 54 to turn on/off, an air pipe 56 in communication with inside of the humidifying chamber 40 therethrough, a valve 58 that is connected to the air pipe 56 and turns on/off the supply of air from an air source (not shown), a solenoid 58A that causes the valve 58 to turn on/off, a humidifying air pipe 60 for supplying humidifying air from the humidifying chamber 40 to the tank 12, an overflow pipe 62 for discharging excess air, a drain pipe 64 for draining, and a drain valve 66 connected to the drain pipe 64.

The humidifying chamber 40 stores pure water within the bottom thereof, and is driven by the atomizing units 42 to produces saturated steam. The saturated steam is in turn mixed with air supplied from the air source such that it is transformed to humidifying air that is supplied to the tank 12 through the humidifying air pipe 60.

A constituent material for the humidifying chamber 40 is not limited if it does not contaminate pure water and can tolerate operation by the atomizing units 42, and stainless steel may preferably be used.

The atomizing unit 42 is fixed on outside of the bottom of the humidifying chamber 40, and serves to atomize pure water when driven and vibrated by the energizing circuit 44. The temperature sensor 48 fixed on the energizing circuit 44 detects an overheat condition of the energizing circuit 44 and is used by a protection circuit (not shown) for protecting the energizing circuit 44.

The level sensor 50 determines the level of pure water in the humidifying chamber 40, and the determined water level signal is sent to the control device 18 that drives the solenoid 54A, causing the valve 54 to turn on/off for controlling the supply of pure water. This arrangement maintains the level of pure water in the humidifying chamber 40 to a predetermined value.

Air supplied through the air pipe 56 is controlled in the amount thereof with the valve 58 turned on/off when the solenoid 58A is driven by the control device 18 that has received a signal from the humidity sensor 14.

The overflow pipe 62 is used for overflow. The drain pipe 64 and drain valve 66 are used, for example, when cleaning the humidifying chamber 40.

The control device 18 comprises a computer 70 that controls the entire slurry preparation apparatus, etc., 10, a sequencer 72, etc., that receives a command from the computer 70 and controls the solenoids 54A and 58A causing them to turn on/off the valves 54 and 58. The control device 18 is also adapted to control the energizing circuit 44 of the atomizing units 42.

Additionally, the computer 70 of the control device 18 is adapted to control the supply of a stock slurry solution supplied from the pipe 20 and an additive from the pipe 22.

Operation of the slurry preparation apparatus, etc. 10 configured as described above will now be described. Pure water is supplied from a pure water source (not shown) through the valve 54 and the pure water pipe 52 to the humidifying chamber 40, and stored within the bottom of the humidifying chamber 40. Simultaneously, air is supplied from an air source (not shown) through the valve 58 and the air pipe 56 to the humidifying chamber 40.

Driven by the atomizing units 42, saturated steam is produced, which is in turn mixed with air supplied from the air source such that it is transformed to humidifying air that is supplied to the tank 12 through the humidifying air pipe 60.

The humidity sensor 14 determines humidity in the tank 12 and the control device 18 controls the operation of the atomizing units 42, the amount of pure water and air supplied, and the like such that an intended value of humidity is maintained.

This maintains an inner wall of the tank 12 in a wet condition. Therefore, although the surface level in the tank 12 falls as much as the slurry is used while the slurry is being supplied, and the slurry could be deposited on a wall surface in the area from the level before the slurry is used down to the level as much as the slurry is used, the deposited slurry would not subsequently dry to coagulate and solidify on the wall surface.

Consequently, coagulated and solidified slurry clod would no longer be produced, and damages on a wafer (microscratches), degraded wafer quality or reduced wafer yield caused by slurry clod with large size would be eliminated.

The relative humidity of 100% in the tank 12 may be sufficient for the present invention to be effective, and maintaining the relative humidity to 90% and more may not impose a problem. The relative humidity of on the order of 85% may not impose a major problem. Even with the relative humidity of 80%, the effect may be more recognizable than a conventional practice. It is therefore preferable to maintain the relative humidity in the tank 12 to 80% and more.

A preferred embodiment of an apparatus for preparing and/or supplying a slurry for a CMP apparatus according to the present invention has been described. The present invention, however, is not limited to the illustrative embodiment described above, and various aspects may be implemented.

For example, although the term “humidifying air” that comprises pure water and air is used, an arrangement that uses water that has generally a similar effect (including pure water and ultra-pure water) and nitrogen gas are within equivalents of the present invention, and may also be implemented.

### EXAMPLE

The slurry preparation apparatus, etc. 10 in a configuration as shown in FIG. 1 was used to carry out CMP for verifying the effect of the present invention. The capacity of the tank 12 was 15 liter, and a colloidal silica slurry from CABOT, type SS-25, was used as a stock slurry solution. IC1000 from Rodel, Inc., was used as a polishing pad. A silicon wafer with an oxide film deposited was used for a working substrate.

Humidity in the tank 12 during operation of the slurry preparation apparatus, etc. 10 was set to 92% and CMP was continuously run for 8 hours. The slurry as it was after the run was used to polish working substrates for the test, and microscratches were counted for polished 5 working substrates. The number of microscratches in plane of a wafer was a few (less than 10) for each working substrate.

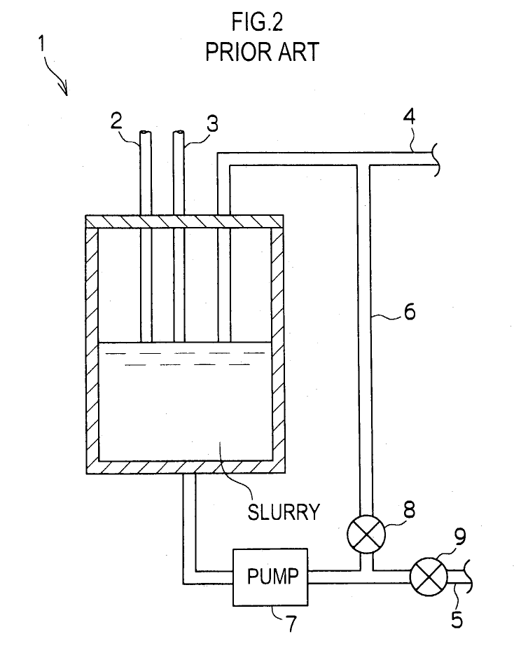

To compare, a used conventional slurry tank (in generally similar configuration as shown in FIG. 2) was used to carry out CMP under the same condition (materials, polishing conditions, etc.) Microscratches were counted for polished 5 working substrates. The number of microscratches in plane of a wafer was on the order of thousands for each working substrate.

Another type of slurry was then used to carry out similar CMP for verifying the effect of the present invention. A fumed-silica slurry from Rodel, Inc., type ILD-1300, was used as a stock slurry solution. Other conditions were the same as the above tests.

Humidity in the tank 12 during operation of the slurry preparation apparatus, etc. 10 was set to 93% and CMP was continuously run for 8 hours. The slurry as it was after the run was used to polish working substrates for the test, and microscratches were counted for polished 5 working substrates. The number of microscratches in plane of a wafer was a few (less than 10) for each working substrate.

To compare, a used conventional slurry tank (in generally similar configuration as shown in FIG. 2) was used to carry out CMP under the same condition (materials, polishing conditions, etc.) Microscratches were counted for polished 5 working substrates. The in-plane number of microscratches was on the order of thousands for each working substrate.

It was thus verified that the present invention has a remarkable effect over a conventional practice with any type of slurry particles.

According to the present invention, humidity in a tank is measured by a sensor capable of measuring the humidity in the tank for preparing the slurry, etc., and the amount of humidifying air to be fed is controlled according to the measurements, as described above. The present invention, therefore, provides for high accuracy for the humidity to be adjusted, the humidity is automatically measured, and the humidifying air is automatically fed.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. An apparatus for preparing and/or supplying a slurry for a CMP apparatus, comprising:
a tank for preparing and/or supplying the slurry;
a humidity sensor located inside the tank; and
a humidifying air supply device for supplying humidifying air into the tank,
wherein humidity in the tank is measured by the humidity sensor, and an amount of the humidifying air to be supplied from the humidifying air supply device is controlled according to the measured humidity in the tank, thereby conditioning inside the tank to a desired humidity.
